(19) United States
(12) Patent Application Publication
(10) Pub. No.: US 2026/0113994 A1
(43) Pub. Date: Apr. 23, 2026

(54) LDMOS TRANSISTOR ARCHITECTURE

(71) Applicant: SEMICONDUCTOR COMPONENTS INDUSTRIES, LLC, Scottsdale, AZ (US)

(72) Inventors: Gang LIU, Camas, WA (US); Santosh MENON, Portland, OR (US)

(73) Assignee: SEMICONDUCTOR COMPONENTS INDUSTRIES, LLC, Scottsdale, AZ (US)

(21) Appl. No.: 18/921,530

(22) Filed: Oct. 21, 2024

(51) Int. Cl. H01L 29/06; H01L 29/10; H01L 29/66; H01L 29/78

(52) U.S. Cl. CPC H10D 62/104; H10D 30/0281; H10D 30/65; H10D 62/393

(57) ABSTRACT

A transistor is disclosed. The transistor includes a source region and a drain region having a first conductivity type. The transistor also includes a channel region located adjacent to the source region and having a second conductivity type. The transistor further includes a drift region located between the drain region and the channel region, the drift region having a drift-region width that is less than a drain-region width of the drain region. In addition, the transistor includes a trench region located adjacent to the drift region on a first side and on a second side of the drift region.

### TECHNICAL FIELD

The disclosure relates generally to integrated circuit technology, and particularly to laterally diffused metal-oxide-semiconductor transistors.

### BACKGROUND

Power electronics may be used to control the conversion and the distribution of electrical power in a number of applications. Power transistors, such as laterally-diffused metal-oxide-semiconductor transistors (LDMOS), may be utilized in power electronics to handle voltages that are higher than those typically used for complimentary MOS (CMOS) circuitry. The breakdown voltage of an LDMOS transistor may be measured as the drain-to-source breakdown voltage with the gate and the source shorted together.

The inventors of embodiments of the present disclosure have recognized that conventional techniques for increasing the breakdown voltage of a power transistor, such as an LDMOS transistor, may result in either a large footprint, additional processing costs, and/or decreased reliability. Embodiments of the present disclosure may address one or more of these challenges.

### BRIEF DESCRIPTION OF THE DRAWINGS

A more complete understanding of the present embodiments may be acquired by referring to the following description taken in conjunction with the accompanying drawings, in which like reference numbers indicate like features.

FIG. 1 illustrates a top view of a transistor in accordance with embodiments of the present disclosure.

FIG. 2 illustrates a perspective cross-sectional view of a transistor in accordance with embodiments of the present disclosure.

FIG. 3 illustrates a perspective cross-sectional view of a transistor in accordance with embodiments of the present disclosure.

FIG. 4 illustrates a top cross-sectional view of adjacent transistors in accordance with embodiments of the present disclosure.

FIG. 5 illustrates a top view of a transistor in accordance with embodiments of the present disclosure.

FIG. 6 illustrates a method for forming a transistor in accordance with embodiments of the present disclosure.

### DETAILED DESCRIPTION

Details of one or more embodiments are set forth in the description below and the accompanying drawings. Other features will be apparent from the description, drawings, and from the claims. The embodiments disclosed should not be interpreted, or otherwise used, as limiting the scope of the disclosure, including the claims. In addition, one skilled in the art understands that the following description has broad application, and the discussion of any embodiment is meant to be exemplary of that embodiment, and not intended to intimate that the scope of the disclosure, including the claims, is limited to that embodiment.

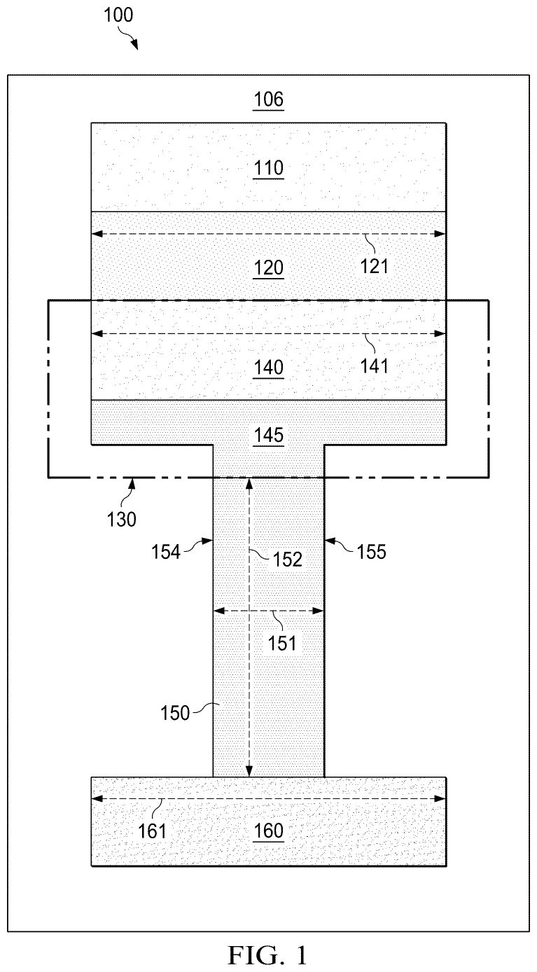

FIG. 1 illustrates a top view of transistor 100 in accordance with embodiments of the present disclosure. As shown in FIG. 1, transistor 100 may be a laterally diffused MOS (LDMOS) transistor, and thus may also be referred to as an LDMOS or LDMOS transistor. As described in detail below, in some embodiments, transistor 100 may be an n-type metal-oxide-semiconductor transistor (NMOS transistor). In other embodiments, transistor 100 may be a p-type metal-oxide-semiconductor transistor (PMOS transistor).

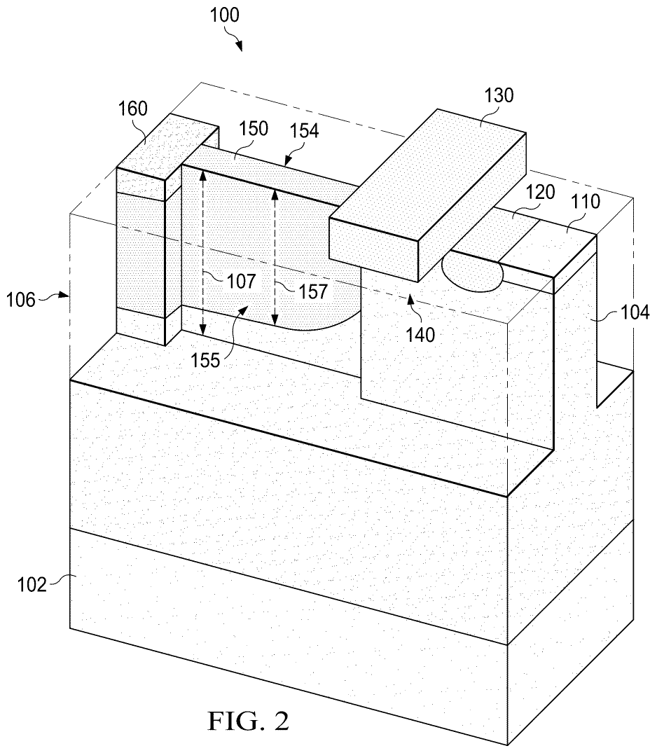

Transistor 100 may include body region 110, source region 120, gate 130, channel region 140, accumulation region 145, drift region 150, and drain region 160. Source region 120 and drain region 160 may have a first conductivity type. For example, in embodiments where transistor 100 is an NMOS transistor, source region 120 and drain region 160 may be n-type regions. And in embodiments where transistor 100 is a PMOS transistor, source region 120 and drain region 160 may be p-type regions. Source region 120 and drain region 160 may be disposed in well region 104 (shown in the perspective view of FIG. 2) having a second conductivity type opposite of the first conductivity type.

Body region 110 may also be disposed in well region 104 and may have a higher doping of the second conductivity type than well region 104. In embodiments where transistor 100 is an NMOS transistor, well region 104 and body region 110 may be p-type regions. And in embodiments where transistor 100 is a PMOS transistor, well region 104 and body region 110 may be n-type regions. As shown in FIG. 1, body region 110 may be located in some embodiments adjacent to source region 120. In other embodiments, body region 110 may be disposed in well region 104 at a location a distance away from source region 120. In some embodiments, body region 110 and source region 120 may be coupled together by one or more contacts and/or metal layers to couple the body of transistor 100 to the source of transistor 100.

Channel region 140 may be located adjacent to source region 120. For example, as shown in FIG. 1, gate 130 may be formed over a portion of well region 104 adjacent to source region 120. Gate 130 may include a polysilicon layer and a gate dielectric formed over well region 104. The portion of well region 104 under gate 130 may form channel region 140. Channel region 140 may accordingly have the second conductivity type opposite of the first conductivity type. For example, in embodiments where transistor 100 is an NMOS transistor, channel region 140 may be a p-type region. And in embodiments where transistor 100 is a PMOS transistor, channel region 140 may be an n-type region.

During manufacture of transistor 100, a drift-layer doping may be applied to well region 104 to form drift region 150. As shown in FIG. 1, drift region 150 may be located between drain region 160 and channel region 140. In some embodiments, the drift-layer doping may be applied not only to drift region 150, but also to portions of well region 104 that will underly gate 130. Accordingly, the drift-layer doping may also form accumulation region 145 under a portion of gate 130 and located between channel region 140 and drift region 150. The drift-layer doping may be of the same conductivity type, but with a lower doping concentration, than the doping for source region 120 and drain region 160. Accordingly, accumulation region 145 and drift region 150 may have the first conductivity type at a lower doping concentration than source region 120 and drain region 160. Specifically, in embodiments where transistor 100 is an NMOS transistor, accumulation region 145 and drift region 150 may be n-type regions with a lower n-type doping concentration than source region 120 and drain region 160. And in embodiments where transistor 100 is a PMOS transistor, accumulation region 145 and drift region 150 may be p-type regions with a lower p-type doping concentration than source region 120 and drain region 160.

Although some embodiments may include accumulation region 145 as shown in FIG. 1, the drift-layer doping area in other embodiments may extend from drift region 150 to the edge, but not past the edge, of gate 130. In such other embodiments, accumulation region 145 may be omitted, and channel region 140 may extend to the edge of gate 130 and directly abut drift region 150. In either such embodiments with or without accumulation region 145, drift region 150 may be referred to as being located between drain region 160 and channel region 140.

As shown in the top view of FIG. 1, drift region 150 may extend laterally from the accumulation region 145 under gate 130 to drain region 160. In embodiments as described above without an accumulation region, drift region 150 may extend laterally from channel region 140 to drain region 160. In some embodiments, drift region 150 may have a drift-region width 151 that is less than a drift-region length 152. Further, as shown in FIG. 1, drift region 150 may have a drift-region width 151 that is less than a drain-region width 161 of drain region 160. For example, the drift-region width 151 may be 75%, 50%, 25%, 10%, or less, of the drain-region width 161. In some embodiments, the drift-region width 151 may also be less than the source-region width 121 of source region 120 and less than the channel-region width 141 of channel region 140. For example, in some embodiments, the source-region width 121, channel-region width 141, and drain-region width 161 may be equal to each other at a width greater than the drift-region width 151 of drift region 150.

As shown in the top view of FIG. 1, the area not occupied by an active area, such as body region 110, source region 120, channel region 140, accumulation region 145, drift region 150, and drain region 160, may be occupied by trench region 106. For example, trench region 106 may surround the other features at the semiconductor surface of transistor 100, including body region 110, source region 120, channel region 140, accumulation region 145, drift region 150, and drain region 160. With respect to drift region 150 in particular, trench region 106 may be located adjacent to drift region 150 on a first side 154 and on a second side 155 of drift region 150.

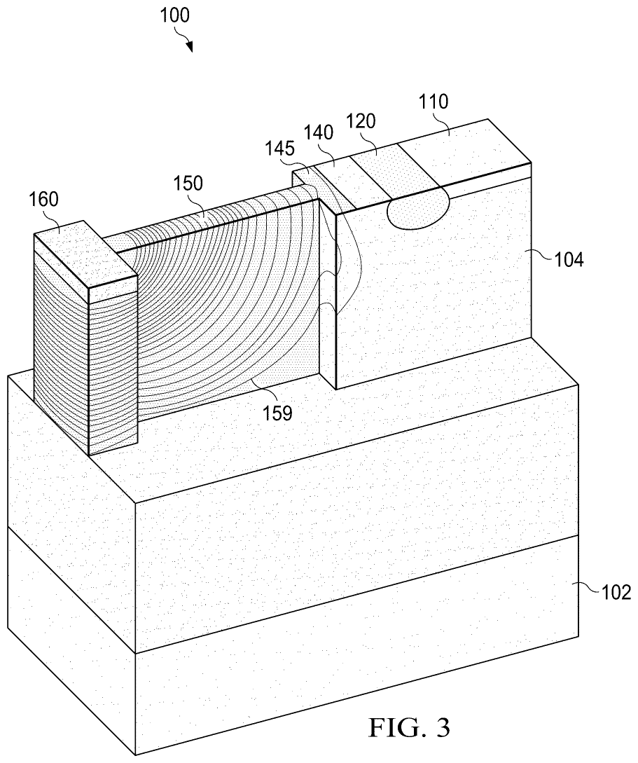

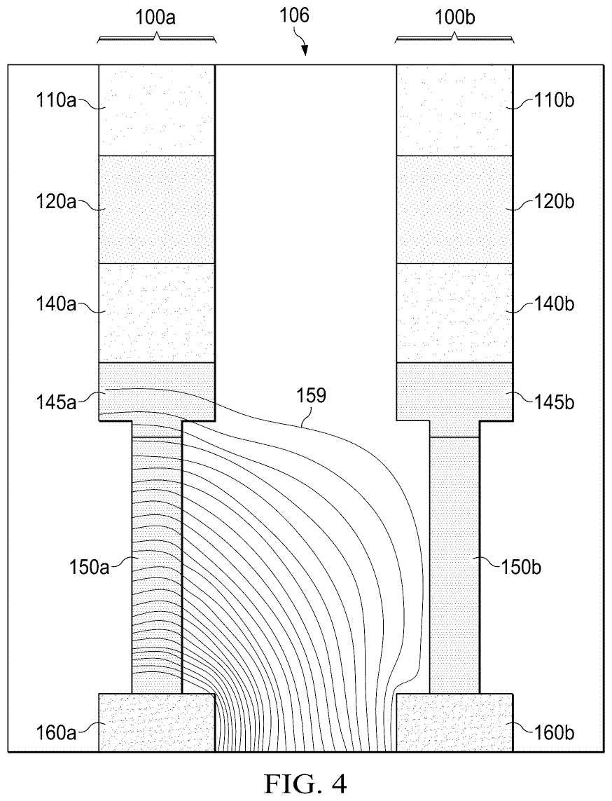

In some embodiments, trench region 106 may be formed by a dielectric material. For example, trench region 106 may comprise silicon dioxide. As explained in further detail below with reference to FIG. 3 and FIG. 4, a dielectric material such as silicon dioxide may provide a more evenly distributed spread of an electric field than, for example, a semiconductor material such as silicon, silicon carbide, or gallium nitride. By utilizing trench region 106 to confine drift region 150 on the first side 154 and the second side 155 of drift region 150, such that drift region 150 has a drift-region width 151 that is less than the drain-region width 161 of drain region 160, the spread of an electric field across drift region 150 during operation of transistor 100 may be predominated by the surrounding silicon dioxide of trench region 106. Accordingly, electric fields incurred by drift region 150 during operation of transistor 100 may be more evenly spread, thereby enhancing the breakdown voltage of transistor 100 for a given area footprint. Further, by utilizing trench region 106 to confine the sides of drift region 150, transistor 100 may conduct in a straight line path from source region 120, through channel region 140 and drift region 150, and to drain region 160, in a straight line path. The enhanced breakdown voltage of transistor 100 may thus be realized without sacrificing significant increases in the on-state resistance of transistor 100.

FIG. 2 illustrates a perspective cross-sectional view of transistor 100 in accordance with embodiments of the present disclosure. As shown in FIG. 2, well region 104 may be formed in a semiconductor substrate that includes epitaxial region 102. The semiconductor substrate and the epitaxial region 102 included therein may be formed by any suitable semiconductor material, such as silicon, silicon carbide, or gallium nitride. And as described above with reference to FIG. 1, each of body region 110, source region 120, channel region 140, drift region 150, and drain region 160 may be disposed in well region 104.

As shown by the perspective view of transistor 100 in FIG. 2, trench region 106 may have a trench depth 107 greater than a drift-region depth 157 of drift region 150. Accordingly, trench region 106 may confine the drift region 150 on the first side 154 and the second side 155 of drift region 150 throughout the entirety of the drift-region depth 157 of drift region 150. Further, by extending below the drift-region depth 157 of drift region 150, trench region 106 may electrically isolate transistor 100 from neighboring instances of transistor 100 and/or other circuit elements disposed in other neighboring areas of well region 104.

FIG. 3 illustrates a perspective cross-sectional view of transistor 100 in accordance with embodiments of the present disclosure. Certain features of transistor 100 are omitted from the perspective view of transistor 100 in FIG. 3 in order to open the view of electric field lines 159. For example, gate 130 and the material forming trench region 106 are omitted from view in FIG. 3.

As described above, the breakdown voltage of a transistor, such as transistor 100, may be measured as the drain-to-source breakdown voltage with the gate and the source shorted together. For example, in embodiments where transistor 100 is an NMOS transistor, the breakdown voltage of transistor 100 may be measured as the drain voltage at which the transistor 100 breaks down when the gate and source of transistor 100 are shorted together and to ground. When the gate and the source of transistor 100 are shorted together, transistor 100 may be held in an off-state with no drain-to-source conduction. When a voltage is applied to the drain in such off-state conditions, that voltage will result in an electric field emanating outward from the drain. FIG. 3 for example illustrates the electric field emanating from drain region 160 under conditions where transistor 100 is an NMOS transistor, 20 volts is applied to the drain of transistor 100, and the source and gate of transistor 100 are both held to 0 volts. Each electric field line 159 may represent a 1-volt drop in the electric field emanating from drain region 160.

A dielectric material such as silicon dioxide may provide a more evenly distributed spread of an electric field than, for example, a semiconductor material such as silicon, silicon carbide, or gallium nitride. For example, whereas a semiconductor material such as silicon may dissipate an electric field across a distance in a more exponential manner, a dielectric material such as silicon dioxide may dissipate an electric field across a distance in a more linear manner. By utilizing trench region 106 to confine the sides of drift region 150 such that drift region 150 has a drift-region width 151 that is less than the drain-region width 161 of drain region 160, the spread of the electric field emanating from drain region 160 and across drift region 150 may be predominated by the surrounding silicon dioxide of trench region 106. Accordingly, the electric fields lines 159 shown in FIG. 3 may be more evenly spread due to the relative widths of drain region 160 and drift region 150, and the presence of trench region 106 confining the sides of drift region 150. By evenly spreading the dissipation of the electric field, crowding of the electric field may be avoided, and the breakdown voltage of transistor 100 for a given area footprint may be enhanced. Further, by utilizing trench region 106 to confine the sides of drift region 150, transistor 100 may conduct in a straight line path from source region 120, through channel region 140 and drift region 150, and to drain region 160. The enhanced breakdown voltage of transistor 100 may thus be realized without sacrificing significant increases in the on-state resistance of transistor 100.

FIG. 4 illustrates a top cross-sectional view of adjacent transistors in accordance with embodiments of the present disclosure. Each of the first transistor 100a and the second transistor 100b may represent an instance of transistor 100 described above with reference to FIG. 1-3. As shown in FIG. 4, trench region 106 may separate first transistor 100a from second transistor 100b, as well as surround the individual features of those respective transistors.

FIG. 4 illustrates the electric field emanating from drain region 160a under conditions where first transistor 100a and second transistor 100b are NMOS transistors, 20 volts is applied to the drain of first transistor 100a, the source and gate of first transistor 100a are both held to 0 volts, and the drain, source, and gate of second transistor 100b are each held to 0 volts. Each electric field line 159 may represent a 1-volt drop in the electric field emanating from drain region 160a.

As described above with reference to FIG. 3, by utilizing trench region 106 to confine the sides of drift region 150a such that drift region 150a has a drift-region width that is less than the drain-region width of drain region 160a, the spread of the electric field emanating from drain region 160a and across drift region 150a may be predominated by the surrounding silicon dioxide of trench region 106. Accordingly, the electric fields lines 159 may be more evenly spread due to the relative widths of drain region 160a and drift region 150a, and the presence of trench region 106 confining the sides of drift region 150a. By more evenly spreading electric field lines 159 in the direction from drain region 160a along drift region 150a, the spread of those electric field lines 159 may also be more evenly distributed in the direction toward second transistor 100b. Accordingly, in addition to enhancing the breakdown voltage of first transistor 100a for a given area footprint, the pitch at which first transistor 100a and second transistor 100b may be instantiated may also be improved. Thus, in power applications requiring multiple instances of transistor 100, the total die area consumed by those instances of transistor 100 may be reduced.

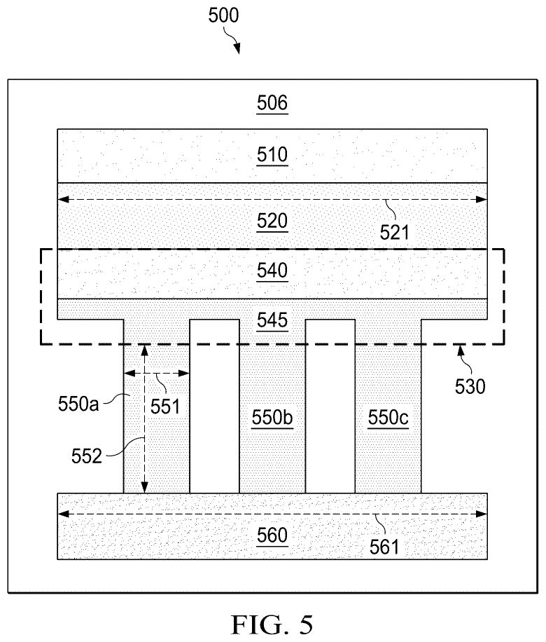

FIG. 5 illustrates a top view of transistor 500 in accordance with embodiments of the present disclosure. As shown in FIG. 5, transistor 500 may be an laterally diffused MOS (LDMOS) transistor, and thus may also be referred to as an LDMOS or LDMOS transistor. As described in detail below, in some embodiments, transistor 500 may be an NMOS transistor. In other embodiments, transistor 100 may be a PMOS transistor.

Transistor 500 may include body region 510, source region 520, gate 530, channel region 540, accumulation region 545, drift region 550, and drain region 560. Source region 520 and drain region 560 may have a first conductivity type. For example, in embodiments where transistor 500 is an NMOS transistor, source region 520 and drain region 560 may be n-type regions. And in embodiments where transistor 500 is a PMOS transistor, source region 520 and drain region 560 may be p-type regions. Source region 520 and drain region 560 may be disposed in a well region having a second conductivity type opposite of the first conductivity type. For example, source region 520 and drain region 560 may be disposed in a well region such as well region 104 described above with reference to FIG. 2.

Body region 510 may be disposed in the same well region as source region 520 and drain region 560. Body region 510 may have a higher doping of the second conductivity type than the well region. In embodiments where transistor 500 is an NMOS transistor, body region 510 and the well region may be p-type regions. And in embodiments where transistor 500 is a PMOS transistor, body region 510 and the well region may be n-type regions. As shown in FIG. 5, body region 510 may be located in some embodiments adjacent to source region 520. In other embodiments, body region 510 may be disposed in the well region at a location a distance away from source region 520. In some embodiments, body region 510 and source region 520 may be coupled together by one or more contacts and/or metal layers to couple the body of transistor 500 to the source of transistor 500.

Channel region 540 may be located adjacent to source region 520. For example, as shown in FIG. 5, gate 530 may be formed over a portion of the well region adjacent to source region 520. Gate 530 may include a polysilicon layer and a gate dielectric formed over the well region. The portion of the well region under gate 530 may thus form channel region 540. Channel region 540 may accordingly have the second conductivity type opposite of the first conductivity type. For example, in embodiments where transistor 500 is an NMOS transistor, channel region 540 may be a p-type region. And in embodiments where transistor 500 is a PMOS transistor, channel region 540 may be an n-type region.

During manufacture of transistor 500, a drift-layer doping may be applied to the well region to form a plurality of drift-region fingers such as drift-region fingers 550a, 550b, and 550c. As shown in FIG. 5, transistor 500 may include a plurality of drift-region fingers 550a, 550b, and 550c disposed in parallel between drain region 560 and channel region 540. Although an embodiment of transistor 500 is shown in FIG. 5 with three drift-region fingers 550a, 550b, and 550c, other embodiments of transistor 500 may include any suitable number drift-region fingers to increase or decrease the cumulative width of the drift-region fingers according to the current conduction requirements and the on-state resistance requirements of a given application. For example, in applications requiring higher current carrying capability and/or lower on-state resistance, transistor 500 may include a larger number of drift-region fingers such as 4, 10, 20, 100, or more.

In some embodiments, the drift-layer doping may be applied not only to the plurality of drift-region fingers 550a, 550b, and 550c, but also to portions of the well region that will underly gate 530. Accordingly, the drift-layer doping may also form accumulation region 545 under a portion of gate 530 and located between channel region 540 and each of the plurality of drift-region fingers 550a, 550b, and 550c. The drift-layer doping may be of the same conductivity type, but with a lower doping concentration, than the doping for source region 520 and drain region 560. Accordingly, accumulation region 145 and each of the drift-region fingers 550a, 550b, and 550c may have the first conductivity type at a lower doping concentration than source region 520 and drain region 560. Specifically, in embodiments where transistor 500 is an NMOS transistor, accumulation region 545 and drift-region fingers 550a, 550b, and 550c may be n-type regions with a lower n-type doping concentration than source region 520 and drain region 560. And in embodiments where transistor 500 is a PMOS transistor, accumulation region 545 and drift-region fingers 550a, 550b, and 550c may be p-type regions with a lower p-type doping concentration than source region 520 and drain region 560.

Although some embodiments of transistor 500 may include accumulation region 545 as shown in FIG. 5, the drift-layer doping area in other embodiments may extend from drift-region fingers 550a, 550b, and 550c to the edge, but not past the edge, of gate 530. In such other embodiments, accumulation region 545 may be omitted, and channel region 540 may extend to the edge of gate 530 and directly abut drift-region fingers 550a, 550b, and 550c. In either such embodiments with or without accumulation region 545, drift-region fingers 550a, 550b, and 550c may be referred to as being located between drain region 560 and channel region 540.

As shown in the top view of FIG. 5, drift-region fingers 550a, 550b, and 550c may extend laterally from the accumulation region 545 under gate 530 to drain region 560. In embodiments as described above without an accumulation region, drift-region fingers 550a, 550b, and 550c may extend laterally from channel region 540 to drain region 560. In some embodiments, each of the plurality of drift-region fingers 550a, 550b, and 550c may have a finger width 551 that is less than a finger length 552 of the drift-region finger. Further, each of the plurality of drift-region fingers 550a, 550b, and 550c may have a finger width 551 that is less than a drain-region width 561 of drain region 560. In some embodiments, the cumulative width of each of the plurality of drift-region fingers 550a, 550b, and 550c, may also be less than the drain-region width 561 of drain region 560. For example, the cumulative width of each of the plurality of drift-region fingers 551, 550b, and 550c, may be 75%, 50%, 25%, 10%, or less, of the drain-region width 561 of drain region 560.

As shown in the top view of FIG. 5, area not occupied by an active area, such as body region 510, source region 520, channel region 540, accumulation region 545, drift region 550, and drain region 560, may be occupied by trench region 506. For example, trench region 506 may surround the other features at the semiconductor surface of transistor 500, including body region 510, source region 520, channel region 540, accumulation region 545, drift region 550, and drain region 560. With respect to the plurality of drift-region fingers 550a, 550b, and 550c, trench region 506 may be located adjacent to each drift-region finger on a first side and on a second side of each drift-region finger. Further, trench region 506 may have a trench-region depth greater than a drift-region depth of each of the plurality of drift-region fingers 550a, 550b, and 550c.

In some embodiments, trench region 506 may be formed by a dielectric material. For example, trench region 506 may comprise silicon dioxide. Similar to the description above with reference to FIG. 3 and FIG. 4, a dielectric material such as silicon dioxide may provide a more evenly distributed spread of an electric field than, for example, a semiconductor material such as silicon, silicon carbide, or gallium nitride. By utilizing trench region 506 to confine the drift-finger widths of each of the plurality of drift-region fingers 550a, 550b, and 550c relative to the drain-region width 561 of drain region 560, the spread of an electric field across each of the plurality of drift-region fingers 550a, 550b, and 550c during operation of transistor 500 may be predominated by the surrounding silicon dioxide of trench region 506. Accordingly, electric fields incurred by the plurality of drift-region fingers 550a, 550b, and 550c during operation of transistor 500 may be more evenly spread, thereby enhancing the breakdown voltage of transistor 500 for a given area footprint.

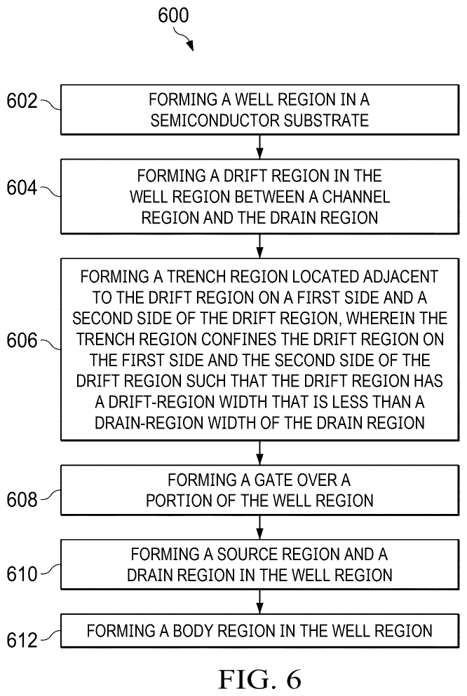

FIG. 6 illustrates method 600 for forming a transistor in accordance with embodiments of the present disclosure. Method 600 may be performed with fewer or more steps than shown in FIG. 6. Moreover, steps of method 600 may be omitted, repeated, performed in parallel, performed in a different order than shown in FIG. 6, or performed recursively. One or more steps of method 600, although shown in an order, may be performed at the same time or in a re-ordered manner.

Step 602 may include forming a well in a semiconductor substrate. For example, as described above with reference to FIG. 2, well region 104 may be formed in a semiconductor substrate that includes epitaxial region 102.

Step 604 may include forming a drift region in the well region between a channel region and the drain region. For example, as described above with reference to FIG. 1 and FIG. 2, a drift-region doping may be applied to form drift region 150 in well region 104. Drift region 150 may be formed between the area that will form channel region 140 and the area that will form drain region 160 according to further process steps described below.

Step 606 may include forming a trench region located adjacent to the drift region on a first side and a second side of the drift region, wherein the trench region confines the drift region on the first side and the second side of the drift region such that the drift region has a drift-region width that is less than a drain-region width of the drain region. For example, as described above with reference to FIG. 1 and FIG. 2, trench region 106 may be located adjacent to drift region 150 on a first side 154 and a second side 155 of drift region 150 such that drift region 150 has a drift-region width 151 that is less than a drain-region width 161 of drain region 160. Trench region 106 may be formed by etching an area of the semiconductor substrate including epitaxial region 102 and filling the etched area with silicon dioxide. In some embodiments, the trench area may be etched at a depth greater than the depth of the drift-region doping. Thus, trench region 106 may have a trench depth greater than a drift-region depth of drift region 150.

Step 608 may include forming a gate over a portion of the well region. For example, as described above with reference to FIG. 1 and FIG. 2, gate 130 may be formed over a portion of well region 104. Gate 130 may include a polysilicon layer and a gate dielectric formed over well region 104. The portion of well region 104 under gate 130 may thus serve as channel region 140.

Step 610 may include forming a source region and a drain region in the well region. For example, as described above with reference to FIG. 1 and FIG. 2, source region 120 and drain region 160 may be formed in well region 104. Source region 120 and drain region 160 may be formed with a first conductivity type opposite to a second conductivity type of well region 104. For example, in embodiments where transistor 100 is an NMOS transistor, well region 104 may be formed as a p-type region, and source region 120 and drain region 160 may be formed as n-type regions. And in embodiments where transistor 100 is a PMOS transistor, well region 104 may be formed as an n-type region, and source region 120 and drain region 160 may be formed as p-type regions.

Step 612 may include forming a body region in the well region. For example, as described above with reference to FIG. 1 and FIG. 2, body region 110 may be formed in well region 104. In some embodiments, body region 110 may be disposed in well region 104 and may have a higher doping of the second conductivity type than well region 104. As shown in FIG. 1, body region 110 may be formed adjacent to source region 120. In other embodiments, body region 110 may be formed in well region 104 at a location a distance away from source region 120. In some embodiments, body region 110 and source region 120 may be coupled together by one or more contacts and/or metal layers to couple the body of transistor 100 to the source of transistor 100.

Although examples have been described above, other modifications and variations may be made from this disclosure without departing from the spirit and scope of these examples. The above descriptions of various embodiments illustrate the principles of the invention. Numerous variations and modifications will become apparent to those skilled in the art based on the above disclosure. The following claims are intended to embrace all such variations and modifications.

What is claimed is:

1. A transistor comprising:
a source region having a first conductivity type;
a channel region located adjacent to the source region and having a second conductivity type;
a drain region having the first conductivity type;
a drift region located between the drain region and the channel region, the drift region having a drift-region width that is less than a drain-region width of the drain region; and
a trench region located adjacent to the drift region on a first side and on a second side of the drift region.

2. The transistor of claim 1, wherein the drift region has the first conductivity type at a lower doping concentration than the source region and the drain region.

3. The transistor of claim 1, wherein the trench region comprises silicon dioxide.

4. The transistor of claim 1, wherein the transistor is an NMOS transistor.

5. The transistor of claim 1, wherein the transistor is PMOS transistor.

6. The transistor of claim 1, wherein the trench region has a trench depth greater than a drift-region depth of the drift region.

7. The transistor of claim 1, wherein the drift-region width of the drift region is less than a drift-region length of the drift region.

8. The transistor of claim 1, further comprising an accumulation region located between the channel region and the drift region.

9. A transistor comprising:
a source region having a first conductivity type;
a channel region located adjacent to the source region and having a second conductivity type;
a drain region having the first conductivity type;
a plurality of drift-region fingers disposed in parallel between the drain region and the channel region; and
a trench region located adjacent to each drift-region finger on a first side and on a second side of each drift-region finger.

10. The transistor of claim 9, wherein each of the plurality of drift-region fingers has the first conductivity type at a lower doping concentration than the source region and the drain region.

11. The transistor of claim 9, wherein the trench region comprises silicon dioxide.

12. The transistor of claim 9, wherein the transistor is an NMOS transistor.

13. The transistor of claim 9, wherein the transistor is PMOS transistor.

14. The transistor of claim 9, wherein the trench region has a trench depth greater than a drift-region depth of each of the plurality of drift-region fingers.

15. The transistor of claim 9, wherein each drift-region finger of the plurality of drift-region fingers has a finger width that is less than a finger length of the drift-region finger.

16. The transistor of claim 9, further comprising an accumulation region located between the channel region and each of the plurality of drift-region fingers.

17. A method for forming a transistor, comprising:
forming a well region in a semiconductor substrate;
forming a drift region in the well region between a channel region and the drain region;
forming a trench region located adjacent to the drift region on a first side and a second side of the drift region, wherein the trench region confines the drift region on the first side and the second side of the drift region such that the drift region has a drift-region width that is less than a drain-region width of the drain region;
forming a gate over a portion of the well region; and
forming a source region and a drain region in the well region.

18. The method of claim 17, wherein the drift-region width of the drift region is less than a drift-region length of the drift region.

19. The method of claim 17, wherein forming the trench region includes etching an area of the semiconductor substrate and filling the area with silicon dioxide.

20. The method of claim 17, wherein the trench region has a trench depth greater than a drift-region depth of the drift region.
